(19) United States
(12) Patent Application Publication
(10) Pub. No.: US 2005/0258545 A1
(43) Pub. Date: Nov. 24, 2005

(54) Multiple die package with adhesive/spacer structure and insulated die surface

(75) Inventor: Hyeog Chan Kwon, Seoul (KR)

Correspondence Address: HAYNES BEFFEL & WOLFELD LLP, P O BOX 366, HALF MOON BAY, CA, 94019, US

(73) Assignee: ChipPAC, Inc., Fremont, CA (US)

(21) Appl. No.: 10/969,303

(22) Filed: Oct. 20, 2004

Related U.S. Application Data
(60) Provisional application No. 60/573,956, filed on May 24, 2004.
(60) Provisional application No. 60/573,903, filed on May 24, 2004.

(51) Int. Cl. H01L 21/48; H01L 23/52

(52) U.S. Cl. 257/777; 438/108; 257/686; 438/109

(57) ABSTRACT

A multiple-die semiconductor chip package (68) has first and second die (42, 44) which define a first, adhesive region (58) therebetween. Wires (20) extend from bond pads (14) on a first die surface (52). The second die has an insulated second die surface (54) positioned opposite the first die surface. An adhesive/spacer structure (46), comprising spacer elements (50) within an adhesive (48), adheres the first and second die to one another. The package may comprise a set of generally parallel wires which defines a wire span portion (60) of the first region. The adhesive/spacer structure is preferably located at other than the wire span portion of the first region. A method for adhering the first and second die to one another is also disclosed.

### CROSS-REFERENCE TO RELATED APPLICATIONS

This application claims priority from U.S. Provisional Application No. 60/573,956, filed May 24, 2004, titled “Multiple die package with adhesive/spacer structure and insulated die surface”[; and this application claims priority from related U.S. Provisional Application No. 60/573,903, filed May 24, 2004, titled “Adhesive/spacer island structure for multiple die package”]. This application is related to U.S. application Ser. No. 10/______ Attorney Docket CPAC 1074-2, filed on the same day as this application.

### BACKGROUND

To obtain the maximum function and efficiency from the minimum package, various types of increased density packages have been developed. Among these various types of packages is the multiple-die semiconductor chip package, commonly referred to as a multi-chip module, multi-chip package or stacked chip package. A multi-chip module includes one or more integrated circuit semiconductor chips, often referred to as circuit die, stacked one onto another to provide the advantages of light weight, high density, and enhanced electrical performance. To stack the semiconductor chips, each chip can be lifted by a chip-bonding tool, which is usually mounted at the end of a pick-and-place device, and mounted onto the substrate or onto a semiconductor chip mounted previously.

In some circumstances, such as when the upper die is smaller than the lower die and the lower die is a peripheral bonded die (that is die with bond pads positioned near the periphery of the die as opposed to a center bonded die in which the bond pads are positioned at a central region of the die), the upper die can be attached directly to the lower die without the use of spacers. However, when spacers are needed between the upper and lower die, spacer die, that is die without circuitry, can be used between the upper and lower die. In addition, adhesives containing spacer elements, typically micro spheres, are often used to properly separate the upper and lower die. See U.S. Pat. Nos. 5,323,060; 6,333,562; 6,340,646; 6,388,313; 6,472,758; 6,569,709; 6,593,662 and U.S. patent Publication No. US 2003/0178710.

After the chip mounting process, bonding pads of the chips are connected to bonding pads of the substrate with Au or Al wires during a wire bonding process to create an array of semiconductor chip devices. Finally, the semiconductor chips and their associated wires connected to the substrate are encapsulated, typically using an epoxy-molding compound, to create an array of encapsulated semiconductor devices. The molding compound protects the semiconductor devices from the external environment, such as physical shock and humidity. After encapsulation, the encapsulated devices are separated, typically by sawing, into individual semiconductor chip packages.

### SUMMARY

A first aspect of the invention is directed to a multiple-die semiconductor chip package. A first die has a first surface bounded by a periphery and bond pads at the first surface. Wires are bonded to and extend from the bond pads outwardly past the periphery. A second die has an electrically non-conductive second surface positioned opposite the first surface. The first and second die define a first region therebetween. An adhesive/spacer structure, comprising spacer elements within an adhesive, is within the first region. The adhesive/spacer structure contacts the first and second surfaces and adheres the first and second die to one another at a chosen separation. The package may comprise a set of generally parallel wires which define a wire span portion of the first region. The adhesive/spacer structure is preferably located at other than the wire span portion of the first region.

A second aspect of the invention is directed to a method for adhering first and second die to one another at a chosen separation in a multiple-die semiconductor chip package. An adhesive/spacer material, having spacer elements within an adhesive, is selected. The adhesive/spacer material is deposited onto a first surface of a first die. The first surface is bounded by a periphery and has bond pads. A set of generally parallel wires is bonded to and extends from the bond pads outwardly past the periphery. The set of generally parallel wires define a wire span portion of the first surface. A second die, having an electrically non-conductive second surface, is selected. The second surface of the second die is located opposite the first surface of the first die and in contact with the adhesive/spacer material therebetween thereby securing the first and second die to one another at a chosen separation, the wire span portion of the first surface defining a wire span region between the first and second surfaces. The adhesive/spacer material is deposited in a manner to prevent any spacer elements from entering the wire span region.

Various features and advantages of the invention will appear from the following description in which the preferred embodiments have been set forth in detail in conjunction with the accompanying drawings.

### BRIEF DESCRIPTION OF THE DRAWINGS

FIG. 1 is a simplified plan view of a conventional peripheral bonded die;

FIG. 2 is a simplified plan view of a conventional center bonded die;

FIGS. 3 and 4 illustrate conventional forward loop and reverse wire bonds;

FIG. 5 is a partial cross sectional view of a multi-die semiconductor assembly made according to the invention;

FIG. 6 is a top plan view of the assembly of FIG. 5 with the periphery of the upper die shown in dashed lines;

FIG. 7 illustrates an alternative embodiment to the assembly of FIG. 6;

FIG. 8 is a side cross sectional view of the assembly of FIGS. 5 and 6;

FIG. 9 shows the assembly of FIG. 8 After encapsulation with a molding compound to create a multiple die semiconductor chip package; and

FIG. 10 illustrates an alternative embodiment similar to that of FIG. 5 in which adhesive fills the wire span portion of the adhesive region; and

FIG. 11 illustrates an alternative embodiment in a view similar to that of FIG. 9 but in which the upper die does not overhang the edge of the lower die, and in which adhesive fills the wire span portion of the adhesive region as in FIG. 10.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGS. illustrating embodiments of the invention, elements corresponding to elements shown in other drawings are not all particularly renumbered, although they are all readily identifiable in all the FIGS.

Several prior art structures and embodiments made according to the invention are discussed below. Like reference numerals refer to like elements.

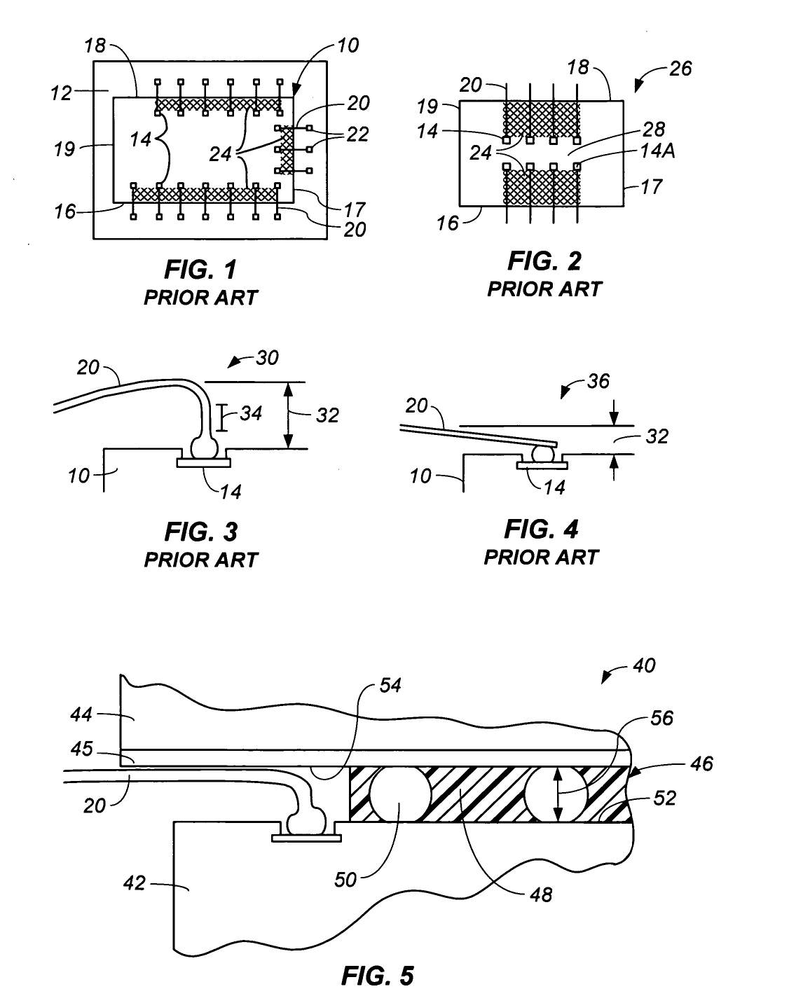

FIG. 1 illustrates a conventional peripheral bonded die 10 mounted to a substrate 12. Die 10 has bond pads 14 along one, some or all of its peripheral edges 16-19. Wires 20 connect bond pads 14 to corresponding bond pads 22 on substrate 12. Wires 20 comprise sets of generally parallel wires along each peripheral edge 16-18 and define wire span areas 24, indicated by crosshatching in FIG. 1, along, such edges. Bond pads 14 on peripheral bonded die 10 are typically placed very close to the corresponding peripheral edge 16-19, typically within 100 micrometers of the peripheral edge.

FIG. 2 illustrates a conventional center bonded die 26, such as a DRAM, having bond pads 14 at a central region 28 of die 26. Wires 20 extending from bond pads 14 define, in this example, wire span areas 24 between the two sets of bond pads 14 and peripheral edges 16, 18. The distance between bond pads 14 and the corresponding peripheral edges for a center bonded die is preferably much more than 100 micrometers. More preferably, the distance between a bond pad 14 for a center bonded die 26 and the nearest peripheral edge is at least about 40% of the corresponding length or width of the die. For example, the distance between a bond pad 14A and peripheral edge 16 is at least about 40% of the length of peripheral edge 17. Assuming peripheral edge 17 is 8 mm long, the distance between bond pad 14A and peripheral edges 16 is at least about 3.2 mm.

FIGS. 3 and 4 illustrate conventional forward loop wire bonding and conventional reverse wire bonding techniques. Forward loop wire bond 30 of FIG. 3 has a wire loop height 32, typically about 60-100 micrometers. Wire 20 has a recrystalization zone 34. Recrystalization zone 34 is not as flexible as the remainder of wire 20 so that excessive flexion of wire 20 within zone 34 may cause wire 22 to break. Therefore, in it is important that wire 20, especially within recrystalization zone 34, not be deformed to any significant degree during manufacturing. This is especially important in the manufacture of multi-chip packages. To reduce the loop height 32 and eliminate recrystalization zone 34 above bond pads 14, a reverse wire bond 36, shown in FIG. 4, may be used. Reverse wire bonds 36 typically have a loop height 32 of about 40-70 micrometers. Forward loop wire bonding, shown in FIG. 5, is often preferred over reverse wire bonding because it has a much larger throughput and the therefore a lower cost.

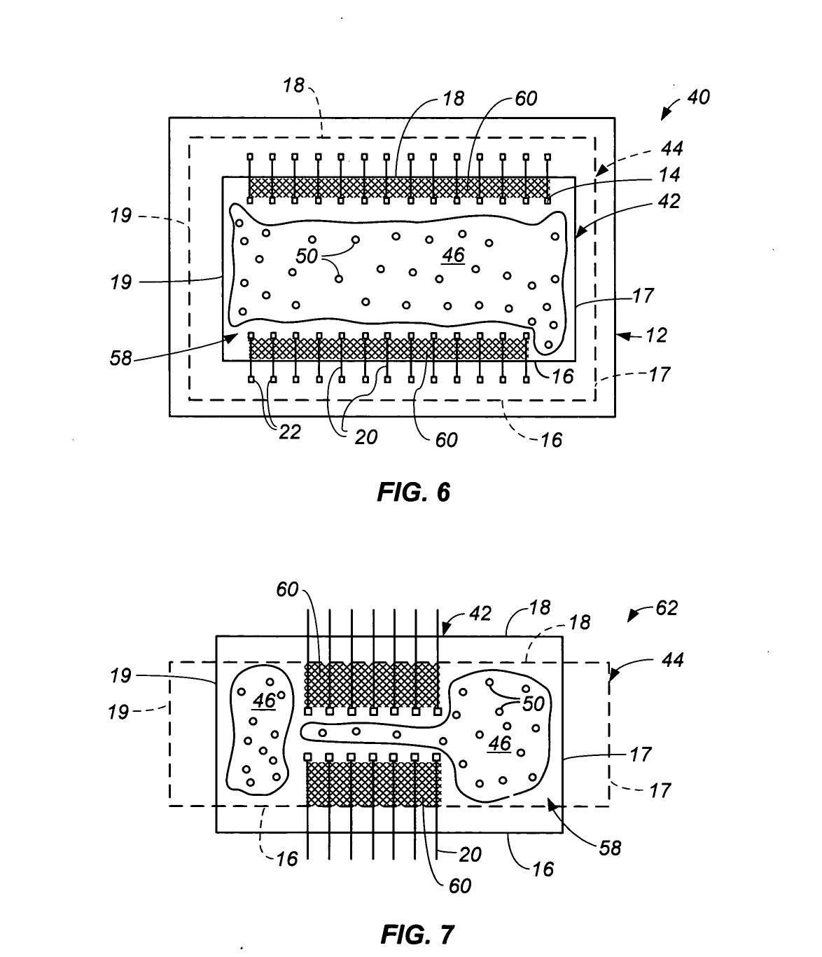

FIG. 5 illustrates a partial cross sectional view of a multi-die semiconductor assembly 40 made according to the invention. Assembly 40 includes a lower, peripheral bonded die 42 and an upper die 44. Assembly 40 protects against shorting of wires 20 against upper die 44 in two basic ways. First, upper die 44 has electrically insulating layer 45, typically a dielectric film adhesive, such as available from Lintec Corporation as Lintec LE5000 or an Hitachi DF series film adhesive. Second, lower die 42, also shown in FIG. 6, is secured to upper die 44 with an adhesive/spacer structure 46. Structure 46 includes adhesive 48 and spacer elements 50. Structure 46 may be a conventional material such as Loctite® QMI536-3, 4, 6, which uses nominal 3, 4 and 6 mil (75, 100 and 150 micrometers) diameter organic polymer spherical particles as spacer elements 50, or a spacer adhesive from the Ablestik 2025 Sx series. It is preferred that spacer elements 50 be of an organic polymer material and pliable and large enough to permit forward loop wire bonding. Spacer elements 50 are typically about 30-250 micrometers in diameter. Structure 56 also helps to provide bond line thickness control and die tilt control. Prevention of the incursion of the adhesive/spacer material, and in particular spacers 50, into wire span portion 60 of first, adhesive region 58 may be achieved by, for example, depositing the adhesive/spacer material at selected positions and carefully controlling the amount deposited at each position. Examples of suitable materials for spacer elements 50 include PTFE and other organic polymers.

Spacer elements 50, prior to use, are typically spherical, ellipsoidal, cylindrical with hemispherical or ellipsoidal ends, or the like. After assembly, assuming spacer elements 50 are compressible, spacer elements 50 are compressed to some degree and have flattened areas where they contact upper surface 52 of lower die 42 and the electrically non-conductive lower surface 54 of upper die 44; the shape of such spacers is collectively referred to as generally ellipsoidal. For example, an initially spherical spacer element 50 having an 8 mil (200 micrometer) diameter will typically compress to a height of about 7.5 mil (188 micrometers). The height 56 of spacers 50, which is equal to the distance between surface 52 and 54, is preferably at least equal to loop height 32, is more preferably greater than loop height 32, is even more preferably at least about 10% greater than loop height 32. If desired, the selection of the spacer elements include selecting spacer elements so that height 56 is equal to the design loop height 32 plus an allowance for manufacturing tolerance build-up resulting from making the wire bonds, the variance in the size and compressibility the of spacer elements 50 and other appropriate variables.

FIG. 6 illustrates assembly 40 with upper die 44 indicated by dashed lines. Lower and upper die 42, 44 define a first, adhesive region 58 therebetween. In the embodiment of FIGS. 5 and 6, region 58 is defined by the periphery of lower die 42 because upper die 44 extends beyond the entire periphery of the lower die. Wire span areas 24, indicated by crosshatching, define wire span portions 60 of first, adhesive region 58. The adhesive/spacer material is deposited in a manner so that, as shown in FIG. 6, adhesive/spacer structure 46 is located at other than wire span portions 60 of first, adhesive region 58. Doing so help to ensure that spacer elements 50 do not interfere with wires 20 thus eliminating the possibility of a spacer element causing one or more wires 22 to deflect to contact and thus short, for example, an adjacent wire 22.

FIG. 7 illustrates a multi-die semiconductor assembly 62 in which lower die 42 is a center bonded die such as shown in FIG. 2 and upper die 44, shown in dashed lines, is longer but narrower than lower die 42. Therefore, in this embodiment first, adhesive region 58 does not cover the entire lower die 42 but rather is bounded by peripheral edges 17 and 19 of lower die 42 and peripheral edges 16 and 18 of upper die 44. Adhesive/spacer structure 46 is, in the embodiment of FIG. 6, located within first, adhesive region 58 at other than wire span portions 60. Adhesive/spacer structure 46 may define a single adhesive/spacer structure region as shown in FIG. 6 or two or more adhesive/spacer structure regions, such as shown in FIG. 7.

Adhesive/spacer material may be deposited using a conventional dispenser capillary. However, it is preferred that the adhesive/spacer material be deposited using a showerhead type of dispenser as shown in the above-mentioned U.S. Provisional Patent Application entitled Adhesive/Spacer Island Structure For Multiple Die Package. Doing so can facilitate the positioning of the adhesive/spacer material at spaced apart locations to provide the desired coverage by adhesive/spacer structure 46. This may be especially advantageous when working with center bonded die.

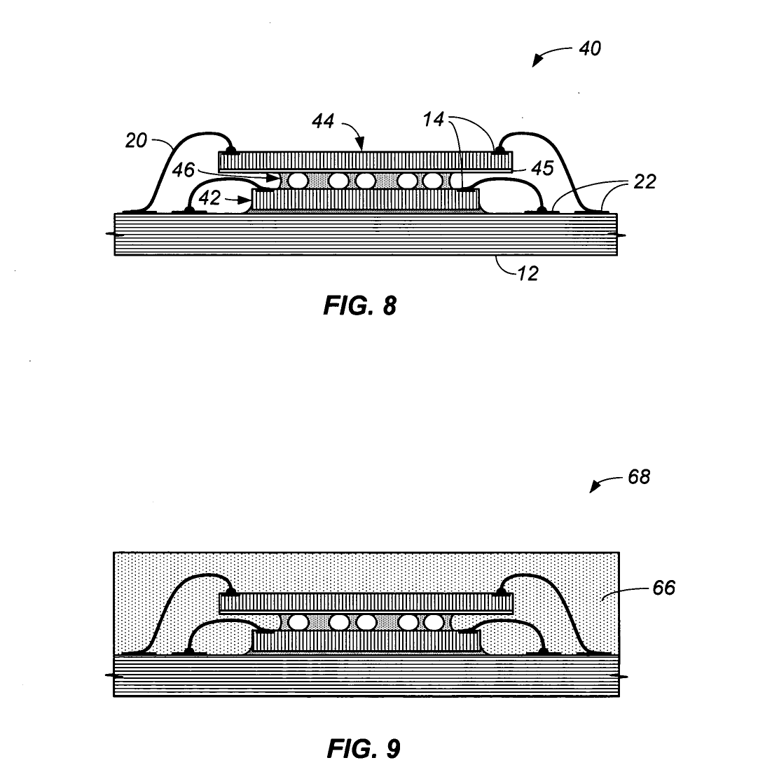

FIG. 8 is a side cross sectional view of multi-die semiconductor assembly 40 of FIGS. 5 and 6 showing wires 20 extending from bond pads 14 of upper die 44 to bond pads 22 of substrate 12. FIG. 9 illustrates the structure of FIG. 8 after a molding compound 66 has been applied to create a multiple die semiconductor chip package 68.

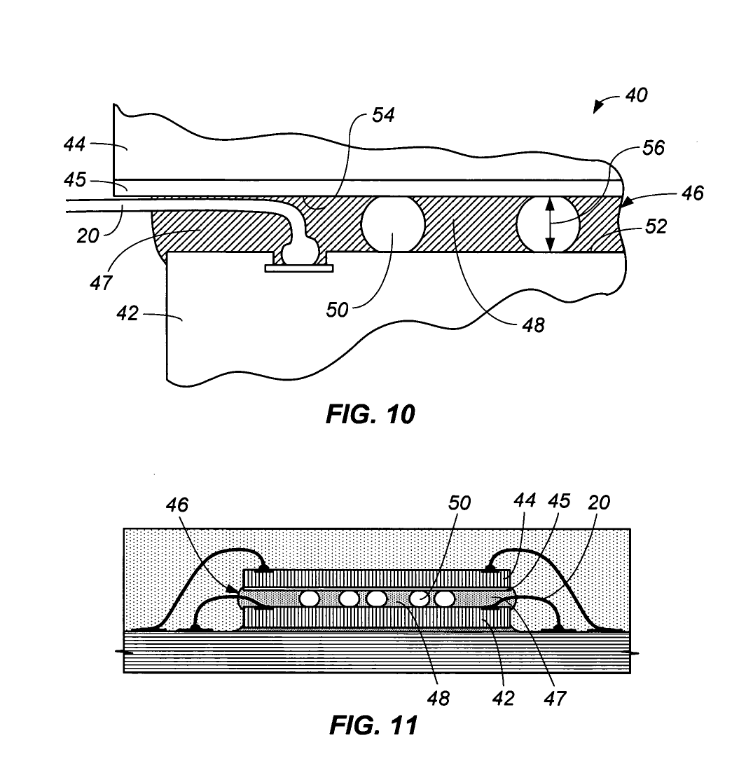

Spacer elements 50 may also be prevented from incursion into wire span portion 60 by sizing the spacer elements so as not to fit between the generally parallel wires 20. In this way wires 20 act as a sieve or strainer to permit a portion 47 of adhesive 48 to enter into wire span portion 60 but prevent spacer elements 50 from doing so. This is illustrated in FIG. 10, showing adhesive/spacer structure 46 including adhesive 48, with spacer elements 50 situated in regions other than the wire span portion of the adhesive region, and showing a portion 47 of adhesive 48 having entered into the wire span portion of the adhesive region. In such embodiments, the spacer elements provide a suitable distance between the two die, the lower surface of the upper die being electrically insulated by dielectric layer 45, as described above with reference to FIG. 5. The full occupancy of adhesive region 58 by adhesive 48, particularly the portion 47 of the adhesive in the wire span region, eliminates the open overhang of the upper die above wires 20 shown in FIG. 5. This provides some support for the upper die, and helps to reduce or eliminate die breakage, which is especially useful for large and thin semiconductor devices.

The adhesive/spacer structure according to the invention can be useful for multi-die assembly structures in which the upper die 44 does not extend over the edge of the lower die 42, as illustrated in FIG. 11, which is a view similar to the view of FIG. 9. Here, as in FIG. 10, spacer structure 46 including spacer elements 50 and adhesive 48 is formed between the upper die 44 with insulating layer 45, and the lower die 42. The wires 20 prevent the spacer elements from entering into the wire span region, but permit a portion 47 of the adhesive 48 to fill the volume there and provide support for the part of the upper 44 die that overhangs the wire loops 20.

Any and all patents, patent applications and printed publications referred to above are incorporated by reference.

Other modification and variation can be made to the disclosed embodiments without departing from the subject of the invention as defined in following claims.

1. A multiple-die semiconductor chip package comprising:
a first die having a first surface bounded by a periphery and having bond pads at the first surface;
wires bonded to and extending from the bond pads outwardly past the periphery, the wires extending to a maximum height h above the first die;
a second die with an electrically non-conductive second surface positioned opposite the first surface;
the first and second die defining a first region therebetween;
an adhesive/spacer structure within the first region, the adhesive/spacer structure contacting the first and second surfaces and adhering the first and second die to one another at a chosen separation, the adhesive/spacer structure comprising spacer elements within an adhesive.

2. The package according to claim 1 wherein the wires comprise a plurality of sets of generally parallel wires, said plurality of sets of generally parallel wires defining a plurality of wire span portions of the first region.

3. The package according to claim 1 wherein the wires comprise a set of generally parallel wires, said set of generally parallel wires defining a wire span portion of the first region.

4. The package according to claim 3 wherein the adhesive/spacer structure is located at other than the wire span portion of the first region.

5. The package according to claim 4 wherein said adhesive is located at the wire span portion of the first region.

6. The package according to claim 5 wherein the spacer elements are sized so as not to fit between the generally parallel wires.

7. The package according to claim 3 wherein the spacer elements are located at other than the wire span portion of the first region.

8. The package according to claim 1 wherein the adhesive/spacer structure defines first and second spaced-apart adhesive/spacer structure regions.

9. The package according to claim 1 wherein the first die has a length and a width and a central region.

10. The package according to claim 9 wherein the first die comprises a center-bonded die with at least some of said die pads positioned at the central region.

11. The package according to claim 10 wherein at least one of the spacer elements is positioned within the central region.

12. The package according to claim 1 wherein the spacer elements have a height H with H being at least about equal to h.

13. The package according to claim 12 wherein H is greater than h.

14. The package according to claim 12 wherein H is at least about 10% greater than h.

15. The package according to claim 1 wherein the spacer elements are generally ellipsoidal.

16. The package according to claim 15 wherein the spacer elements are flattened spheres.

17. The package according to claim 15 wherein the spacer elements are about 30 um-250 um in diameter.

18. The package according to claim 1 wherein the spacer elements are all substantially the same size.

19. The package according to claim 1-wherein the spacer elements comprise an organic and pliable solid material.

20. The package according to claim 1 wherein the spacer elements comprise at least PTFE.

21. A method for adhering first and second die to one another at a chosen separation in a multiple-die semiconductor chip package, the method comprising:
selecting an adhesive/spacer material having spacer elements within an adhesive;
depositing the adhesive/spacer material onto a first surface of a first die, the first die having a first surface bounded by a periphery, bond pads at the first surface, and wires bonded to and extending from the bond pads outwardly past the periphery, the wires extending to a maximum height h above the first die, the wires comprising a set of generally parallel wires, the set of generally parallel wires defining a wire span portion of the first surface;
selecting a second die having an electrically non-conductive second surface;
locating the second surface of the second die opposite the first surface of the first die and in contact with the adhesive/spacer material therebetween thereby securing the first and second die to one another at a chosen separation, the wire span portion of the first surface defining a wire span region between the first and second surfaces; and
preventing any spacer elements from entering the wire span region.

22. The method according to claim 21 further comprising preventing any adhesive/spacer material from entering the wire span region.

23. The method according to claim 21 wherein the preventing step comprises using spacer elements sized so as not to fit between the generally parallel wires.

24. The method according to claim 21 wherein the depositing step is carried out a manner to prevent any adhesive/spacer material from entering the wire span region.

25. The method according to claim 21 wherein the selecting step is carried out to select spacer elements having the same size and shape.

26. The method according to claim 21 wherein the depositing step is carried out with the first die having a length and a width and a central region.

27. The method according to claim 26 wherein the depositing step is carried out with the first die comprising a center-bonded die with at least some of said die pads positioned at the central region.

28. The method according to claim 27 wherein depositing step comprises positioning at least some of the adhesive/spacer material within the central region so that at least one spacer element is positioned within the central region.

29. The method according to claim 21 wherein the adhesive/spacer material selecting step comprises selecting spacer elements having a height H with H being at least about equal to h.

30. The method according to claim 29 wherein the spacer elements selecting step comprises selecting spacer elements in which H is greater than h.

31. The method according to claim 29 wherein the spacer elements selecting step comprises determining an allowance for manufacturing tolerance buildup and selecting spacer elements so that H is equal to h plus the allowance for the manufacturing tolerance buildup.

32. The method according to claim 29 wherein the spacer elements selecting step comprises determining an allowance for manufacturing tolerance buildup and selecting spacer elements so that H is greater than h plus the allowance for the manufacturing tolerance buildup.

33. The method according to claim 29 wherein the spacer elements selecting step comprises selecting spacer elements so that H is at least about 10% greater than h.
